(19) United States
(12) Patent Application Publication
(10) Pub. No.: US 2024/0125842 A1
(43) Pub. Date: Apr. 18, 2024

(54) METHOD FOR DETERMINING THE TEMPERATURE CHARACTERISTIC OF THE DRAIN-SOURCE ON-STATE RESISTANCE OF A MOSFET

(71) Applicant: Robert Bosch GmbH, Stuttgart (DE)

(72) Inventor: Georg Schill, Pforzheim (DE)

(21) Appl. No.: 18/263,979

(22) PCT Filed: Mar. 15, 2022
(86) PCT No.: PCT/EP2022/056597

§ 371 Date: Aug. 2, 2023

(30) Foreign Application Priority Data
Apr. 1, 2021 (DE) 10 2021 203 322.9

(51) Int. Cl. G01R 31/26; G01K 7/18; G01R 19/10

(52) U.S. Cl. CPC G01R 31/2628; G01K 7/183; G01R 19/10

(57) ABSTRACT

A method for determining the temperature characteristic of the drain-source on-state resistance of a MOSFET of a first type. The method includes: determining temperature-specific linearization coefficients of a difference between a first value of the drain-source on-state resistance at a first temperature and a second value of the drain-source on-state resistance at a reference temperature established for the MOSFET-type characterization based on a difference between a first value of the drain-source on-state resistance at the same reference temperature and the average of the drain-source on-state resistance at the same reference temperature from measurements during production for MOSFET samples of the first type; determining the temperature dependency of the determined temperature-specific linearization coefficients to determine a specific TDDR for the characterized MOSFET samples of the first type; and using the MOSFET-type-specific TDDR to reconstruct the temperature dependency of the drain-source on-state resistance of an individual MOSFET of the first type.

### FIELD

The present invention relates to a method for determining the temperature characteristic of the drain-source on-state resistance of a MOSFET and to an arrangement for carrying out the method.

### BACKGROUND INFORMATION

A metal-oxide-semiconductor field-effect transistor (MOSFET) is a field-effect transistor with an insulated gate. In the following, this also includes a so-called MISFET (metal-insulator-semiconductor field-effect transistor), in which a non-oxidic dielectric is used.

In a MOSFET, a current flow in a semiconductor region between the two terminals drain and source is controlled via a control voltage, the gate-source voltage, or via a control potential at a third terminal, the so-called gate. A number of variables are responsible for the behavior of the MOSFET; in the present case, the drain-source on-resistance or drain-source on-state resistance, which in turn depends on the temperature, among other things, is considered in more detail.

The temperature behavior of a drain-source on-state resistance of a MOSFET is usually described with defined test boundary conditions, in particular concerning the gate-source voltage, on the basis of its typical temperature properties, in many cases normalized to its typical value at 25° C. The description is additionally supplemented by the specification of the typical and maximum limit values at a temperature of 25° C. and at a maximum operating temperature. However, this is less often undertaken at different temperatures. The minimum values of the drain-source on-state resistance are specified even less often, in particular at multiple temperatures. In this connection, reference is made to FIG. 1.

A more precise specification of the temperature behavior of the drain-source on-state resistance of a MOSFET, which would allow the latter to be used as a current sensor for a precise current measurement, is presently not available.

The main reasons for this are the economically unreasonable effort for repeated measurement of each individual transistor at different temperatures in mass production, and the lack of a method which allows the temperature behavior of the drain-source on-state resistance to be described or analyzed precisely on the basis of the analysis data or characterization data of a few representative samples.

### SUMMARY

A method and an arrangement for determining the temperature characteristic of the drain-source on-state resistance of a MOSFET are provided according to the present invention. Example embodiments of the present invention are disclosed herein.

According to an example embodiment of the present invention, the method for determining the temperature characteristic of the drain-source on-state resistance of a MOSFET comprises the following steps: determining the temperature-specific linearization coefficients of a difference between a first value of the drain-source on-state resistance at a first temperature and a second value of the drain-source on-state resistance at a reference temperature established for the MOSFET-type characterization on the basis of a difference between a first value of the drain-source on-state resistance at the same reference temperature and the average of the drain-source on-state resistance at the same reference temperature from the measurements during production, in particular mass production, for a number of MOSFET samples of the same type; determining the temperature dependency of the temperature-specific linearization coefficients determined in the first step, in order to determine a temperature-dependent delta resistance (TDDR) specific to the characterized MOSFET type; and using the MOSFET-type-specific TDDR for a reconstruction of the temperature dependency of the drain-source on-state resistance of an individual MOSFET or a circuit of a plurality of MOSFETs of the same MOSFET type.

The method according to the present invention is described below in conjunction with a MOSFET. It should be noted that the designation MOSFET herein also includes a so-called MISFET (metal-insulator-semiconductor field-effect transistor), in which a non-oxidic dielectric is used.

The analysis method presented according to the present invention herein enables a precise description of the temperature dependency of the drain-source on-state resistance of each individual MOSFET of the MOSFET type characterized by means of this method on the basis of the specific temperature-dependent delta resistance (TDDR) determined for this MOSFET type and on the basis of the value of the drain-source on-state resistance of the individual MOSFET at the reference temperature which is established in the analysis method, but which is expediently not necessarily equal to the characterization temperature of the drain-source on-state resistance in MOSFET mass production or equal to the calibration temperature of the drain-source on-state resistance of a MOSFET to be used as a current sensor or of a MOSFET group in control device production. This is particularly important when a MOSFET or a circuit of a plurality of MOSFETs of the same type is used as an exact or precise current sensor. The MOSFET-type-specific TDDR is expediently determined on the basis of the characterization data or analysis data of a small number of representative samples. In this way, the related art can be enhanced.

The use of the drain-source on-state resistance of a MOSFET as a precise current sensor allows a significant cost reduction in the implementation of the redundant current measurements which are required in particular in safety-critical applications, such as in autonomous or automated driving. It is then not necessary to use special components, such as measuring resistors or other current sensors based on the Hall effect, magneto-resistive or other effects, for the current measurement. In addition, the properties of components, such as used MOSFETs, which are already installed in the system can be used. Moreover, there are no additional power losses. This simplifies the thermal design of control devices and reduces the product costs. In addition, the operating temperature of the control units can be reduced, which increases the reliability of these control units with regard to the fault mechanisms associated with high operating temperatures.

The arrangement according to an example embodiment of the present invention is configured to carry out the method according to the present invention, and is implemented, for example, in a piece of hardware and/or software. This software can be stored as a computer program on a machine-readable storage medium.

The arrangement can also be integrated into a measuring arrangement for the characterization of the MOSFET in MOSFET production or be designed as such.

Further advantages and embodiments of the present invention can be found in the description and the figures.

Of course, the features mentioned above and those still to be explained below can be used not only in the respectively specified combinations, but also in other combinations or alone, without departing from the scope of the present invention.

### BRIEF DESCRIPTION OF THE DRAWINGS

FIG. 1 shows, in a graph, the most frequently encountered specification type of a normalized typical temperature dependency of the drain-source on-state resistance.

FIGS. 2 to 19 show, in graphs, curves of different variables in relation to the one-dimensional or two-dimensional TDDR.

FIG. 20 shows, in highly simplified, purely schematic form, an example arrangement for carrying out the method of the present invention.

### DETAILED DESCRIPTION OF EXAMPLE EMBODIMENTS

The present invention is represented schematically in the figures on the basis of embodiments and is described in detail below with reference to the figures.

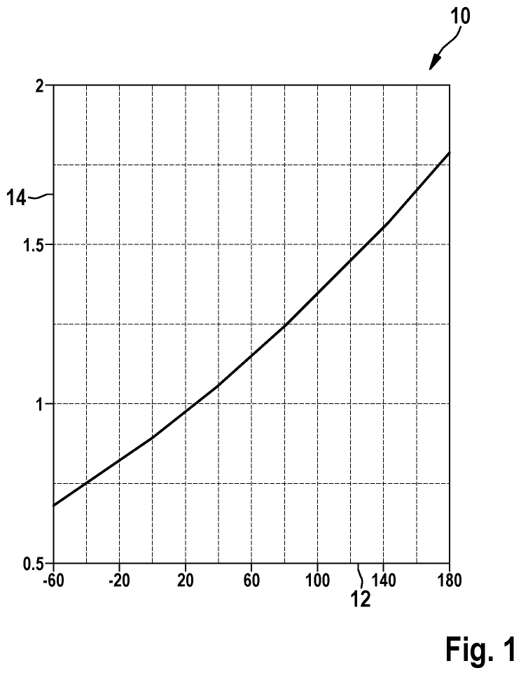

FIG. 1 shows the temperature dependency of the drain-source on-state resistance in a graph 10, on the abscissa 12 of which the temperature T_{J} [° C.] is plotted, and on the ordinate 14 of which the normalized drain-source on-state resistance R_{DS(on), norm}=R_{DS(on)}/R_{DS(on)} @25° C. is plotted. The following applies:

R_{DS(on),norm}=f(Tⱼ);I_{D}=100 A;V_{GS}=10 V

| | | | | | | |
|---|---|---|---|---|---|---|
| Drain-source | R_{DS(on)} | V_{GS} = 10 V, | — | 0.86 | 1.06 | mΩ |
| on-state | | I_{D} = 100 A | | | | |
| resistance | | V_{GS} = 10 V, | — | 1.52 | 1.88 | |
| | | I_{D} = 100 A, | | | | |
| | | Tⱼ = 175° C.¹⁾ | | | | |

Tⱼ denotes the junction temperature.

As has already been stated, a precise specification of the temperature behavior of the drain-source on-state resistance of each individual MOSFET, which would allow the latter to be used as a current sensor for a precise current measurement, has not been available so far.

The so-called temperature-dependent delta resistance (TDDR) is discussed below. In the process, the presented method is explained in more detail.

The TDDR denotes a temperature-dependent component of the drain-source on-state resistance independent of the proportional MOSFET-individual drain-source on-state resistance value at the reference temperature R(ϑ_{Ref}). The sum of the two produces the resulting temperature dependency of the drain-source on-state resistance for each individual MOSFET of the same type, which was characterized by means of this method on the basis of a representative number of samples, in conjunction with its individual drain-source on-state resistance at the reference temperature R(ϑ_{Ref}). This means that for a complete description of the temperature dependency of the drain-source on-state resistance of each individual MOSFET of the characterized MOSFET type, only its individual drain-source on-state resistance at the reference temperature R(ϑ_{Ref}), for example RDS(on) @25, and the specific TDDR determined for this MOSFET type are needed. The boundary conditions relating to the gate-source control voltage during operation must be identical to those during the characterization, e.g. Vgs=10 V.

Step 1: Determining the temperature-specific linearization coefficients of the difference R(ϑ)−R(ϑ_{Ref}) as a function of the difference R(ϑ_{Ref})−R̅_{Ref} for the representative number of MOSFET samples of the same type.

$$A = [ \begin{matrix}{R}_{1} ( {ϑ}_{R e f} ) - {\overline{R}}_{R e f} & 1 \\ … & … \\ {R}_{k - 1} ( {ϑ}_{R e f} ) - {\overline{R}}_{R e f} & 1 \\ {R}_{k} ( {ϑ}_{R e f} ) - {\overline{R}}_{R e f} & 1\end{matrix} ] , \qquad ( 1 )$$

$${\overline{R}}_{R e f} = {lim}_{n \to ∞} \frac{1}{n} * {\sum }_{1}^{n} {R}_{i} ( {ϑ}_{R e f} ) \approx mean [ R ( {ϑ}_{R e f} ) ]$$

$$Y ( {ϑ}_{i} ) = [ \begin{matrix}{R}_{1} ( {ϑ}_{i} ) - {R}_{1} ( {ϑ}_{R e f} ) \\ … \\ {R}_{k - 1} ( {ϑ}_{i} ) - {R}_{k - 1} ( {ϑ}_{R e f} ) \\ {R}_{k} ( {ϑ}_{i} ) - {R}_{k} ( {ϑ}_{R e f} )\end{matrix} ] \qquad ( 2 )$$

$$[ \begin{matrix}{α}_{T D D R} ( {ϑ}_{i} ) \\ {β}_{T D D R} ( {ϑ}_{i} )\end{matrix} ] = ( Y ( {ϑ}_{i} ) * {A}^{T} ) * {( A * {A}^{T} )}^{- 1}$$

ϑ_{Ref}—reference temperature, typically 25° C.
R̅_{Ref}—average of the resistance at ϑ_{Ref}, typically at 25° C., in mass production
ϑᵢ—ith characterization temperature
R_{k(ϑ}_{ᵢ}₎—characterization resistance of the kth sample at the ith characterization temperature

$$[ \begin{matrix}α ( {ϑ}_{i} ) \\ β ( {ϑ}_{i} )\end{matrix} ]$$

linearization coefficients for ith characterization temperature

Step 2: Determining the higher-order, in particular second-order, temperature dependency of the linearization coefficients over the temperature range of interest and determining the MOSFET-type-specific temperature dependency of the delta resistance (TDDR).

$$A = [ \begin{matrix}{ϑ}_{1}^{2} & {ϑ}_{1} & 1 \\ … & … & … \\ {ϑ}_{i - 1}^{2} & {ϑ}_{i - 1} & 1 \\ {ϑ}_{i}^{2} & {ϑ}_{i} & 1\end{matrix} ] \qquad ( 3 )$$

$$α = [ \begin{matrix}α ( {ϑ}_{1} ) \\ … \\ α ( {ϑ}_{i - 1} ) \\ α ( {ϑ}_{i} )\end{matrix} ] \qquad ( 4 )$$

$$β = [ \begin{matrix}β ( {ϑ}_{1} ) \\ … \\ β ( {ϑ}_{i - 1} ) \\ β ( {ϑ}_{i} )\end{matrix} ] \qquad ( 5 )$$

$$[ \begin{matrix}{p}_{2 , α} \\ {p}_{1 , α} \\ {p}_{0 , α}\end{matrix} ] = {( {A}^{T} * A )}^{- 1} * ( {A}^{T} * α ) \qquad ( 6 )$$

$$[ \begin{matrix}{p}_{2 , β} \\ {p}_{1 , β} \\ {p}_{0 , β}\end{matrix} ] = {( {A}^{T} * A )}^{- 1} * ( {A}^{T} * β ) \qquad ( 7 )$$

two-dimensional TDDR

$$T D D {R}_{2 D} ( ϑ , R ( {ϑ}_{R e f} ) - {\overline{R}}_{R e f} ) = {[ \begin{matrix}{p}_{2 , α} \\ {p}_{1 , α} \\ {p}_{0 , α}\end{matrix} ]}^{T} * [ \begin{matrix}{ϑ}^{2} \\ ϑ \\ 1\end{matrix} ] * [ R ( {ϑ}_{R e f} ) - {\overline{R}}_{R e f} ] + {[ \begin{matrix}{p}_{2 , β} \\ {p}_{1 , β} \\ {p}_{0 , β}\end{matrix} ]}^{T} * [ \begin{matrix}{ϑ}^{2} \\ ϑ \\ 1\end{matrix} ] \qquad ( 8 )$$

one-dimensional TDDR

$$T D D {R}_{1 D} ( ϑ ) = {[ \begin{matrix}{p}_{2 , β} \\ {p}_{1 , β} \\ {p}_{0 , β}\end{matrix} ]}^{T} * [ \begin{matrix}{ϑ}^{2} \\ ϑ \\ 1\end{matrix} ] = {p}_{2 , β} * {ϑ}^{2} + {p}_{1 , β} * ϑ + {p}_{0 , β} \qquad ( 9 )$$

Step 3: Using the TDDR for the reconstruction of the temperature dependency of the drain-source on-state resistance of a specific MOSFET of the same MOSFET type as characterized or used for determining the MOSFET-type-specific temperature-dependent delta resistance (TDDR) on the basis of the value of the drain-source on-state resistance R(ϑ_{Ref}) measured at the reference temperature θϑ_{Ref}, usually at 25° C., and the average of the typical resistance R̅_{Ref}, at the same reference temperature, obtained using the measurements in mass production.

R(ϑ)=R(ϑ_{Ref})+TDDR_{2D}(ϑ,R(ϑ_{Ref})−R̅_{Ref})≈R(ϑ_{Ref})+TDDR_{1D}(ϑ) (10)

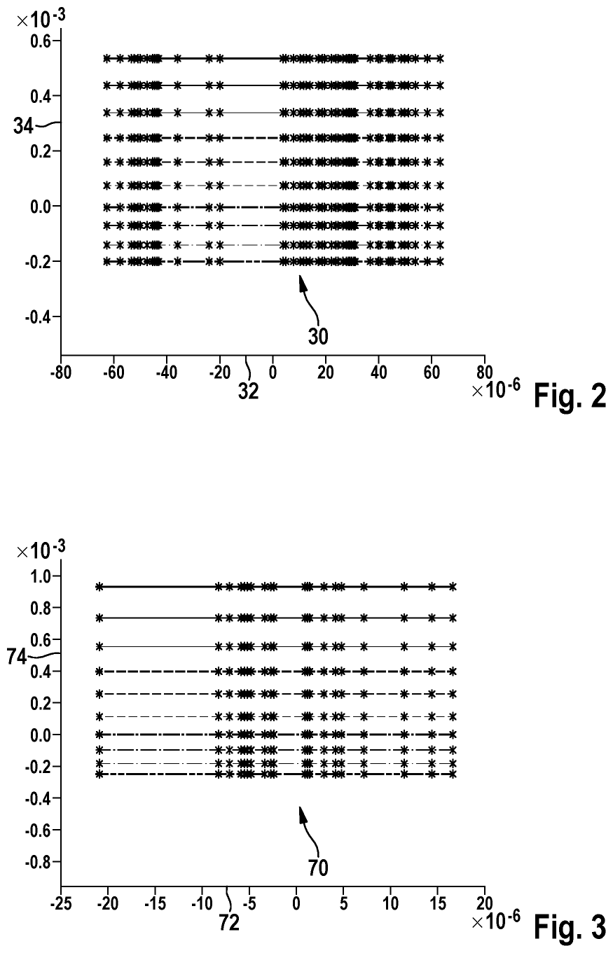

FIG. 2 shows the temperature dependency of the TDDR for a MOSFET type 1 for different junction characterization temperatures in a parameter representation, wherein the junction characterization temperature is used as the parameter, in a graph 30, on the abscissa 32 of which R(25° C.)−R25 [R×10⁻⁶] is plotted, and on the ordinate 34 of which R(T)−R(25° C.) [R×10⁻³] is plotted.

FIG. 3 shows the temperature dependency of the TDDR for a MOSFET type 2 for different junction characterization temperatures in a parameter representation, wherein the junction characterization temperature is used as the parameter, in a graph 70, on the abscissa 72 of which R(25° C.)−R25 [R×10⁻⁶] is plotted, and on the ordinate 74 of which R(T)−R(25° C.) [R×10⁻³] is plotted.

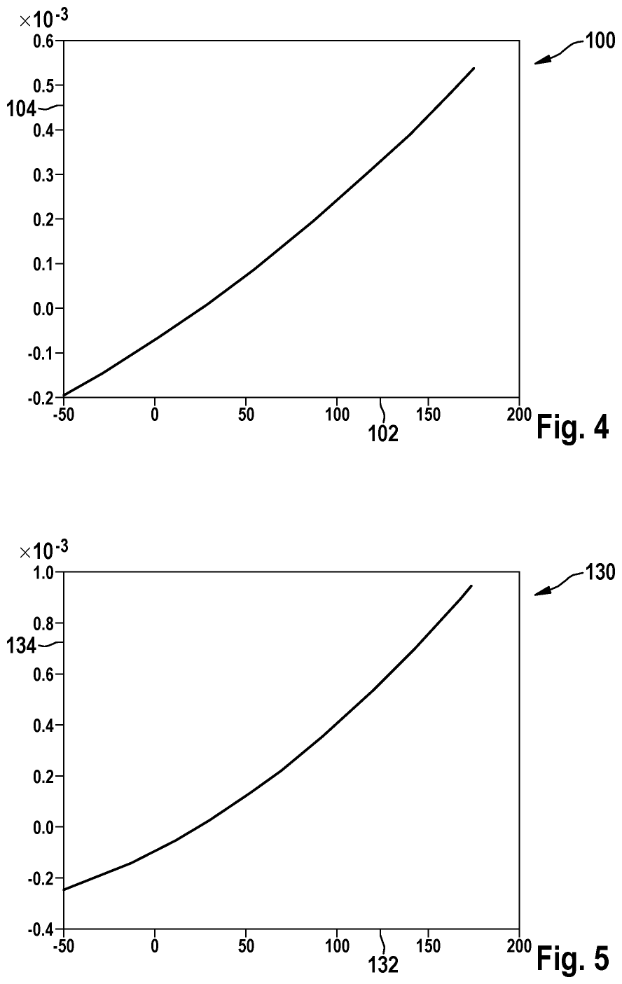

FIG. 4 shows the curve of the one-dimensional TDDR for the MOSFET type 1 in a graph 100, on the abscissa 102 of which T [° C.] is plotted, and on the ordinate 104 of which R(T)−R(25° C.) [R×10⁻³] is plotted.

FIG. 5 shows the curve of the one-dimensional TDDR for the MOSFET type 2 in a graph 130, on the abscissa 132 of which T [°] is plotted, and on the ordinate 134 of which R(T)−R(25° C.) [R×10⁻³] is plotted.

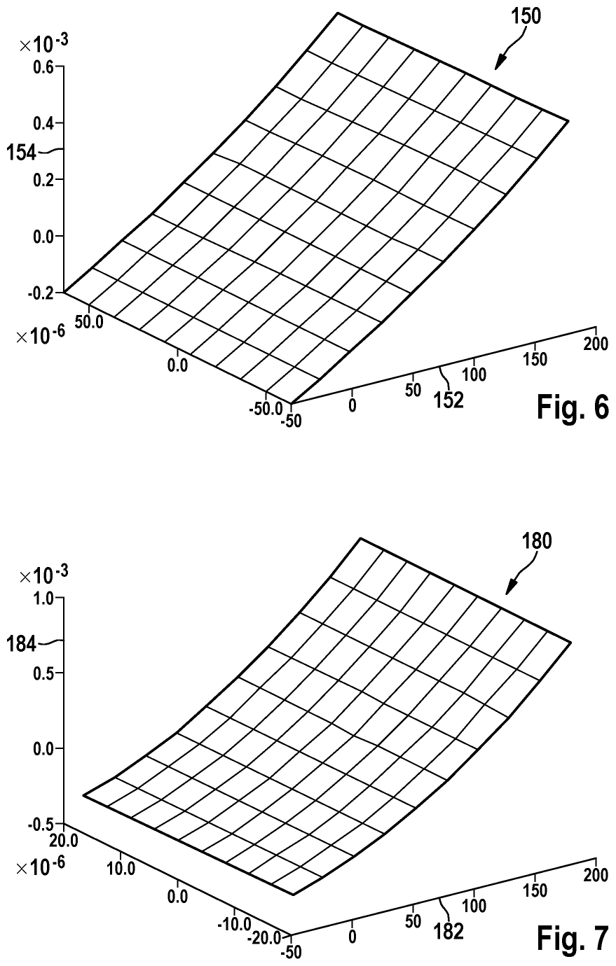

FIG. 6 shows the two-dimensional TDDR for the MOSFET type 1 in a graph 150, on the abscissa 152 of which T [° C.] is plotted, and on the ordinate 154 of which R(T)−R(25° C.) [R×10⁻³] is plotted.

FIG. 7 shows the two-dimensional TDDR for the MOSFET type 2 in a graph 180, on the abscissa 182 of which T [° C.] is plotted, and on the ordinate 184 of which R(T)−R(25° C.) [R×10⁻³] is plotted.

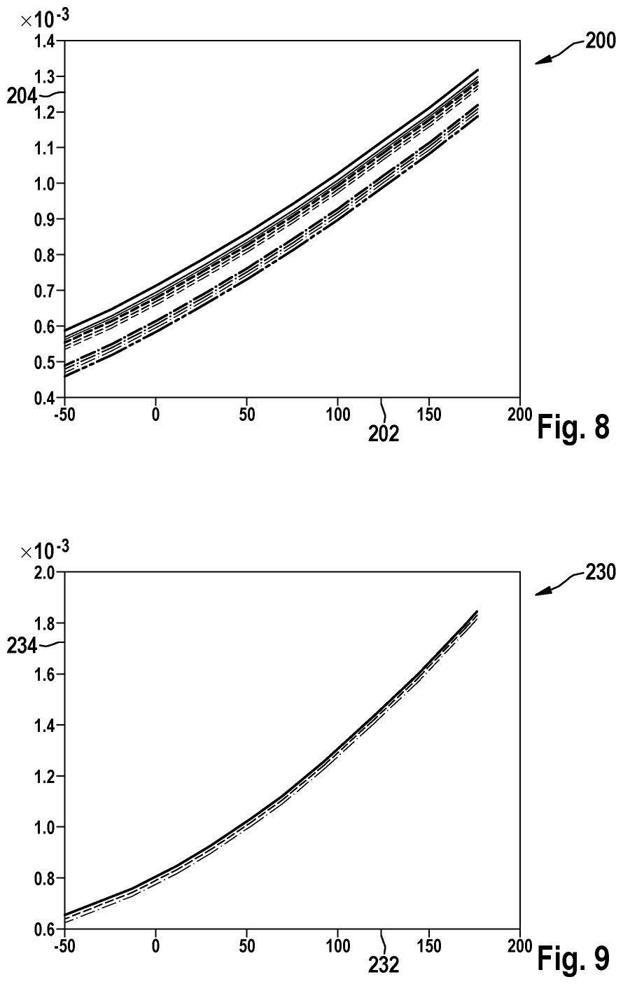

FIG. 8 shows the exemplary application of the one-dimensional TDDR to the MOSFET type 1 for different MOSFETs of this type in a graph 200, on the abscissa 202 of which T [° C.] is plotted, and on the ordinate 204 of which R(T) [R×10⁻³] is plotted.

FIG. 9 shows the exemplary application of the one-dimensional TDDR to the MOSFET type 2 for different MOSFETs of this type in a graph 230, on the abscissa 232 of which T [° C.] is plotted, and on the ordinate 234 of which R(T) [R×10⁻³] is plotted.

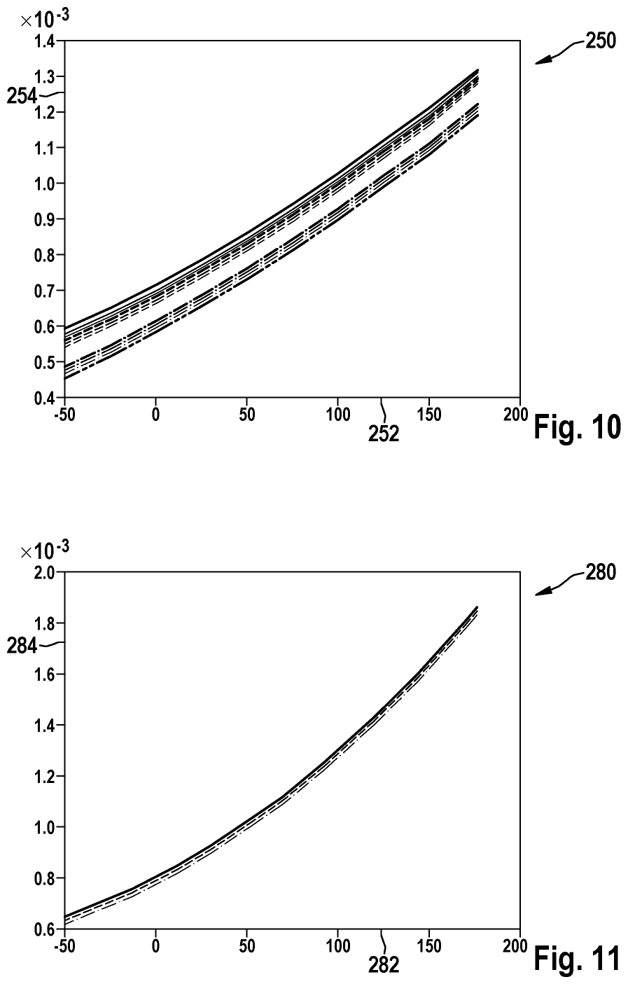

FIG. 10 shows the exemplary application of the two-dimensional TDDR to the MOSFET type 1 for different MOSFETs of this type in a graph 250, on the abscissa 252 of which T [° C.] is plotted, and on the ordinate 254 of which R(T) [R×10⁻³] is plotted.

FIG. 11 shows the exemplary application of the two-dimensional TDDR to the MOSFET type 2 for different MOSFETs of this type in a graph 280, on the abscissa 282 of which T [° C.] is plotted, and on the ordinate 284 of which R(T) [R×10⁻³] is plotted.

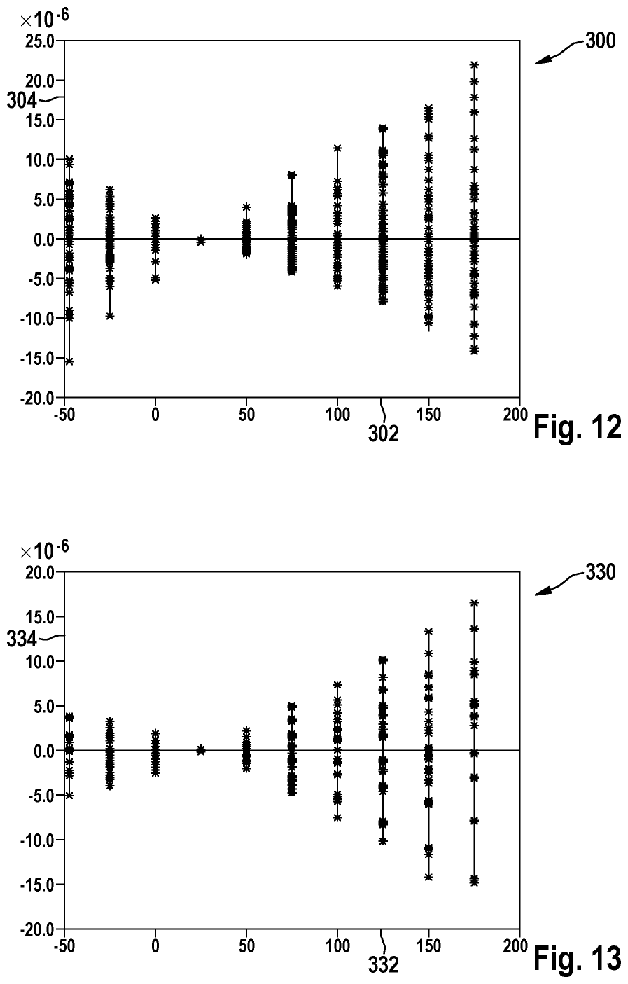

FIG. 12 shows the absolute error of the Rds(ϑ) for the MOSFET type 1 using the one-dimensional TDDR in a graph 300, on the abscissa 302 of which T [° C.] is plotted, and on the ordinate 304 of which ΔR(T) [R×10⁻⁶] is plotted.

FIG. 13 shows the absolute error of the Rds(ϑ) for the MOSFET type 2 using the one-dimensional TDDR in a graph 330, on the abscissa 332 of which T [° C.] is plotted, and on the ordinate 334 of which ΔR(T) [R×10⁻⁶] is plotted.

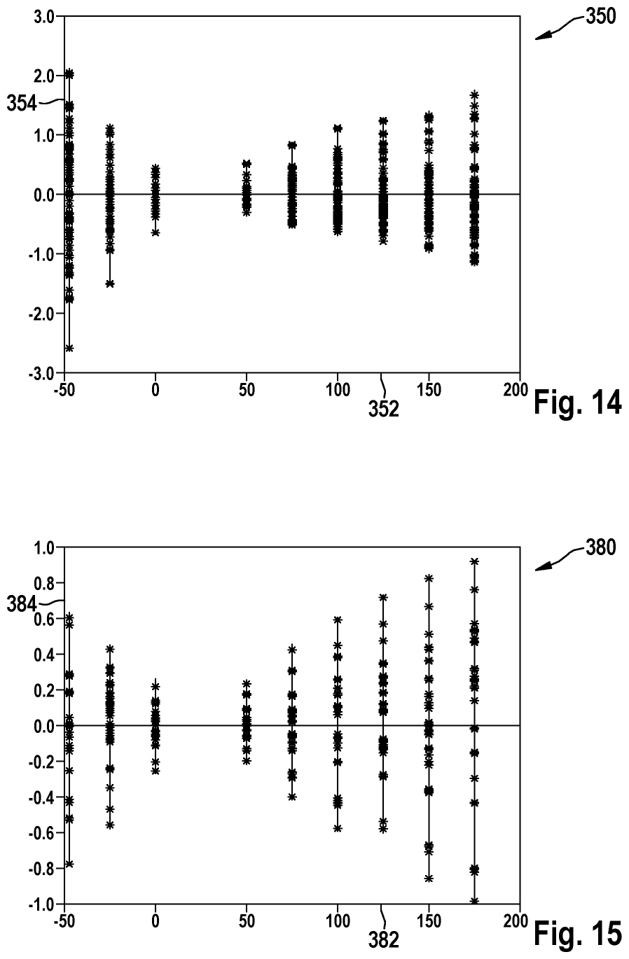

FIG. 14 shows the relative error of the Rds(ϑ) for the MOSFET type 1 using the one-dimensional TDDR in a graph 350, on the abscissa 352 of which T [° C.] is plotted, and on the ordinate 354 of which ΔR(T)/R(T) [%] is plotted.

FIG. 15 shows the relative error of the Rds(ϑ) for the MOSFET type 2 using the one-dimensional TDDR in a graph 380, on the abscissa 382 of which T [° C.] is plotted, and on the ordinate 384 of which ΔR(T)/R(T) [%] is plotted.

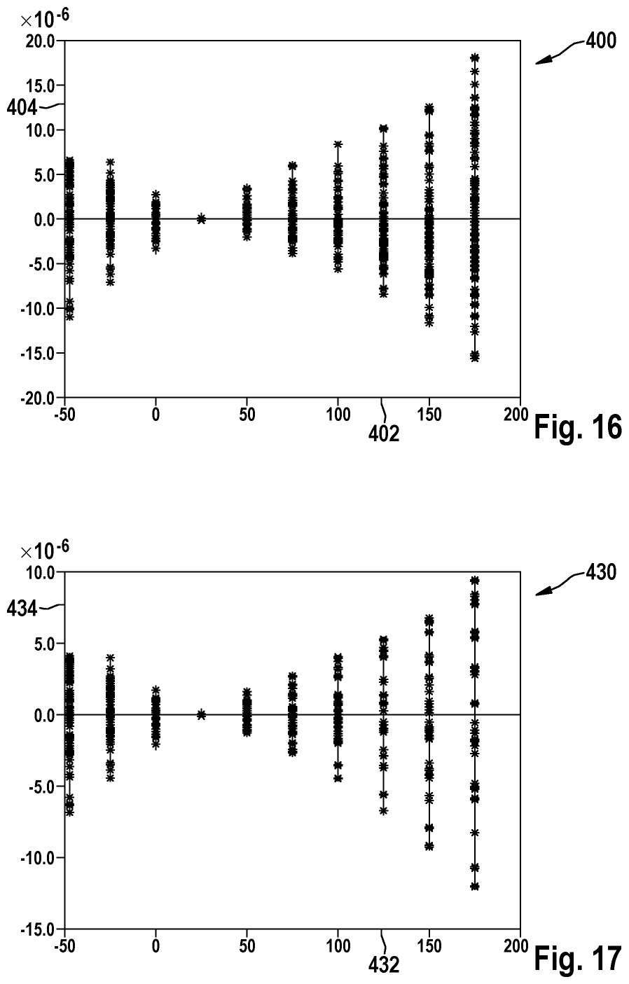

FIG. 16 shows the absolute error of the Rds(ϑ) for the MOSFET type 1 using the two-dimensional TDDR in a graph 400, on the abscissa 402 of which T [° C.] is plotted, and on the ordinate 404 of which ΔR(T) [R×10⁻⁶] is plotted.

FIG. 17 shows the absolute error of the Rds(ϑ) for the MOSFET type 2 using the two-dimensional TDDR in a graph 430, on the abscissa 432 of which T [° C.] is plotted, and on the ordinate 434 of which ΔR(T) [R×10⁻⁶] is plotted.

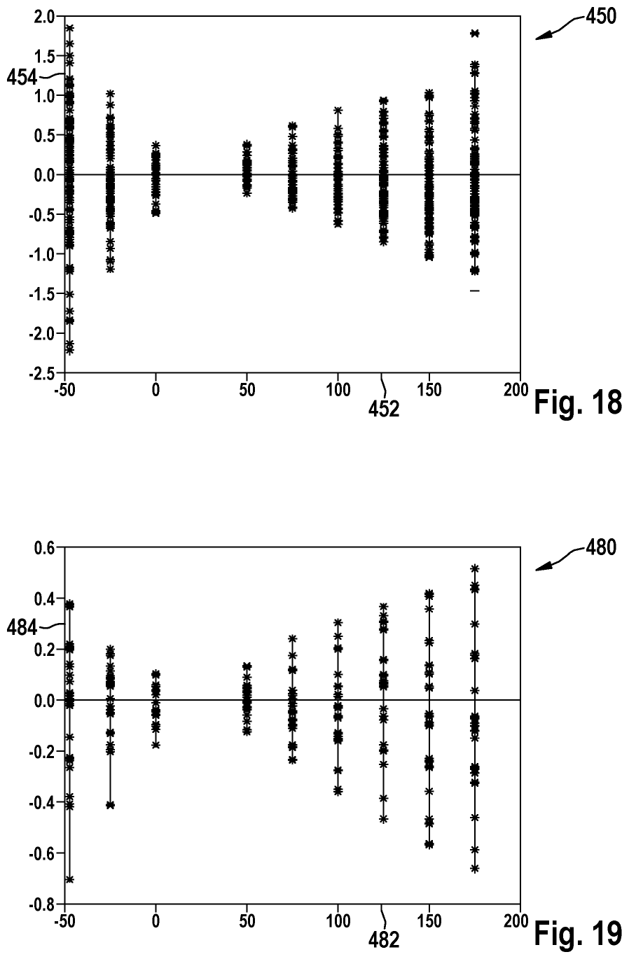

FIG. 18 shows the relative error of the Rds(ϑ) for the MOSFET type 1 using the two-dimensional TDDR in a graph 450, on the abscissa 452 of which T [° C.] is plotted, and on the ordinate 454 of which ΔR(T)/R(T) [%] is plotted.

FIG. 19 shows the relative error of the Rds(ϑ) for the MOSFET type 2 using the two-dimensional TDDR in a graph 480, on the abscissa 482 of which T [° C.] is plotted, and on the ordinate 484 of which ΔR(T)/R(T) [%] is plotted.

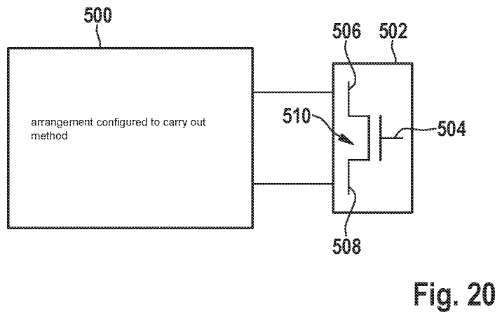

FIG. 20 shows, purely schematically and highly simplified, an arrangement for carrying out the described method, which is denoted overall by the reference numeral 500. This arrangement 500 can be integrated in a measuring arrangement for the characterization of the MOSFET in MOSFET production or be designed as such. The arrangement 500 can be used to examine a MOSFET 502 or any number of MOSFETs of different types. This MOSFET 502 comprises a gate terminal 504, a drain terminal 506 and a source terminal 508. The temperature characteristic of a drain-source on-state resistance 510 of the MOSFET 502 is determined.

1-10. (canceled)

11. A method for determining a temperature characteristic of a drain-source on-state resistance of a MOSFET of a first type, comprising the following steps:
determining temperature-specific linearization coefficients of a difference between a first value of the drain-source on-state resistance at a first temperature and a second value of the drain-source on-state resistance at a reference temperature established for a MOSFET-type characterization based on a difference between a first value of the drain-source on-state resistance at the same reference temperature and an average of the drain-source on-state resistance at the same reference temperature from measurements during production for a number of MOSFET samples of the first type;
determining a temperature dependency of the determined temperature-specific linearization coefficients to determine a temperature-dependent delta resistance (TDDR) specific to the characterized number of MOSFET samples of the first type; and
using the MOSFET-type-specific TDDR for a reconstruction of the temperature dependency of the drain-source on-state resistance of at least one individual MOSFET of the first type.

12. The method according to claim 11, wherein the MOSFET-type-specific TDDR is applied in a circuit of a plurality of MOSFETs of the first type.

13. The method according to claim 11, wherein the MOSFET-type-specific TDDR is used to take into account the temperature characteristic of the drain-source on-state resistance of a MOSFET for representation of a current measurement function.

14. The method according to claim 11, wherein a temperature dependency of the temperature-specific linearization coefficients is determined.

15. The method according to claim 11, wherein the MOSFET-type-specific TDDR is a one-dimensional TDDR.

16. The method according to claim 11, wherein the MOSFET-type-specific TDDR is a two-dimensional TDDR.

17. The method according to claim 11, wherein the reference temperature is equal to a specification temperature of a typical drain-source on-state resistance of a MOSFET in production, or the reference temperature is equal to a calibration temperature of the drain-source on-state resistance of a MOSFET to be used as a current sensor or of a MOSFET group in control device production.

18. The method according to claim 11, wherein the method is used in conjunction with a safety-critical application.

19. An arrangement for determining a temperature characteristic of a drain-source on-state resistance of a MOSFET, the arrangement being configured to:
determine temperature-specific linearization coefficients of a difference between a first value of the drain-source on-state resistance at a first temperature and a second value of the drain-source on-state resistance at a reference temperature established for a MOSFET-type characterization based on a difference between a first value of the drain-source on-state resistance at the same reference temperature and an average of the drain-source on-state resistance at the same reference temperature from measurements during production for a number of MOSFET samples of the first type;
determine a temperature dependency of the determined temperature-specific linearization coefficients to determine a temperature-dependent delta resistance (TDDR) specific to the characterized number of MOSFET samples of the first type; and
use the MOSFET-type-specific TDDR for a reconstruction of the temperature dependency of the drain-source on-state resistance of at least one individual MOSFET of the first type.

20. The arrangement according to claim 19, wherein the arrangement is integrated in a measuring arrangement for characterization of the MOSFET in MOSFET production or is configured to be included in the measuring arrangement.
